(19) United States
(12) Patent Application Publication
(10) Pub. No.: US 2008/0211353 A1
(43) Pub. Date: Sep. 4, 2008

(54) HIGH TEMPERATURE BIMORPH ACTUATOR

(76) Inventors: Charles Erklin Seeley, Niskayuna, NY (US); Dirk Bellamy, Salem, OR (US); Eladio Clemente Delgado, Burnt Hills, NY (US); Jan Kunzmann, Chemnitz (DE)

Correspondence Address: General Electric Company;Global Patent Operation, 187 Danbury Road, Suite 204, Wilton, CT, 06897-4122, US

(21) Appl. No.: 11/681,484

(22) Filed: Mar. 2, 2007

(51) Int. Cl. H01L 41/08

(52) U.S. Cl. 310/359

(57) ABSTRACT

A bimorph actuator has been found that uses commonly available piezoelectric material and is operational up to about 150° C. or one half of Curie temperature, in that it does not exhibit depolarization due to negative electric fields and/or elevated temperature. This result is accomplished by driving both piezoelectric materials with a positive electric field along the polarization direction.

### FIELD OF THE INVENTION

This invention relates to bimorph actuators that have the ability to bend and that also have large displacement capabilities. In particular, this application relates to bimorph actuators comprising piezoelectric materials and which are operational over large changes in temperature.

### BACKROUND OF THE INVENTION

Actuators are devices which transform an input signal (mainly an electrical signal) into motion. Many types of acutators are known and available, but none of them meet the characteristics desired, such as a small space requirment, the ability to operate at elevated temperatures and no requirement of additional pumps and resevoirs. Bimorph actuators are bender actuators and are generally comprised of two elongated strips or layers of active material which are glued together, usually with an additional passive material or substrate in the middle. The top material is actuated out of phase with the bottom material to produce a net bending motion and transverse deflection of the beam like structure. This motion is typically used to make or break an electrical circuit by causing one contact on the bimorph to touch or move away from a second contact.

It is known in the art for the active materials of bimorph actuators to be piezoelectric materials. Piezoelectric materials are those that change shape or deform as a result of being subjected to an electric field. This phenomenam is known as the piezoelectric effect. Both the direction and the magnitude of the piezoelectric material deformation depends on the direction and the magnitude of the applied electric field. That is, a positive or negative voltage causes the material to expand or contract. The deformation due to the application of voltage is highly directionally dependent and relative to the applied electric field and direction of polarization used to induce the piezoelectric properties in the materials. If an actuator has only one piezoelectric element, the actuator will exhibit substantial deflection due to temperature change. This is because of an unbalanced design, i.e. one that is not symetric. One side expands more than the other and results in unwanted displacement from the temperature change.

Piezoelectric materials exist in both naturally occurring and man-made form. Examples of naturally occurring piezoelectric materials are quartz, topaz and Rochelle salt (sodium potassium tartrate tetrahydrate). Naturally occurring materials exhibit relatively low piezoelectric effect, as compared to man-made or industrial pieolectric materials. One example of a common industrial pieolectric material is PZT (lead zirconate titinate). U.S. Pat. No. 6,629,341 discloses a method of fabricating a piezoelectric macro-fiber composite actuator, wherein the piezoelectric material is sliced to provide a pluarlity of piezoelectric fibers in juxtaposition.

The polarization of the active material can be lost as a result of a combination of time, temperature and applied electric field opposite of the direction of polarization. For example, it has been found that a common piezoelectric material, PZT 5A, loses its piezoelectric properties (i.e. it depolarizes) above about 150° C. if the electric field is applied along the direction of polarization. However, this temperature is reduced to only about 50° C. if the electric field is applied opposite the direction of polarization. Since both positive and negative fields are required to operate a conventional bimorph actuator, the temperature limit is much lower than otherwise possible due to depolarization at elevated temperature and negative electric field. For instance, as shown in the accompanying FIG. 1A, if both the negative voltage and positive voltage are applied to the top 100 active material parallel to the direction of the force 120, with polarization 140 in the plane of the material, in this case horizontal, such that the electric field in the positive charged field 130 is in the same direction as the polarization 140, then the positive voltage will cause the active material 100 to expand. On the bottom active material 110, the negative charge results in an electric field 150 which is parallel to the direction of force 170, but is in the opposite direction of the polarization 160 causing that active material 110 to contract.

A similar result is exhibited in FIG. 1B, wherein the electric field is applied perpendicular to the direction of force. In this case, the top active material 200 is subjected to a negative voltage, and the electric field 220 and the polarization 230 are in opposite but parallel directions to each other while being perpendicular to the beam 201, and cause the active material 200 to contract. For the bottom active material 210, a positive electric field 240 is perpendicular to the beam 201, but is parallel and in the same direction as the polarization 250, resulting in a contracting force 270.

The results in both the illustrations of FIGS. 1A and 1B is the depolarization at relatively low temperatures, about 50° C. for PZT 5A active material.

Therefore, it is desirable for a bimorph actuator comprising piezoelectric material that does not exhibit the problem of depolarization due to electric fields at an extended temperature range.

It is also desirable for such a bimorph actuator to be of a size that it functions in small spaces, and not require additional resources such as pumps.

### SUMMARY OF THE INVENTION

A bimorph actuator has been found that uses commonly available piezoelectric material and is operational up to about 150° C. or one half of Curie temperature, in that it does not exhibit depolarization due to negative electric fields and/or elevated temperature. This result is accomplished by driving both piezoelectric materials with a positive electric field along the direction of polarization.

### BRIEF DESCRIPTION OF THE DRAWINGS

Refer now to the figures, which are meant to be exemplary and not limiting, and wherein like elements are numbered alike, and not all numbers are repeated in every figure for clarity of the illustration.

FIG. 1A is an example of a known bimorph actuator that exhibits depolarization at high temperature.

FIG. 1B is an example of a known bimorph actuator that exhibits depolarization at high temperature.

FIG. 2 is an illustrative embodiment of a bimorph actuator that does not exhibit depolarization at high temperature.

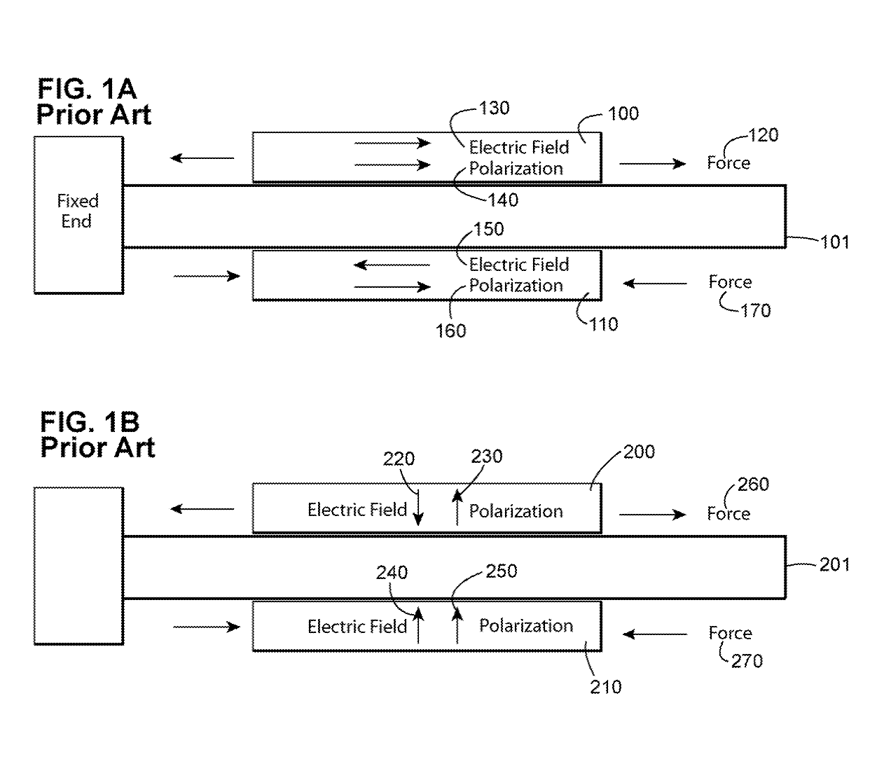

### DETAILED DESCRIPTION OF THE INVENTION

The present invention is a novel bimorph actuator that avoids the problem of depolarization due to negative electric fields. In one embodiment of the bimorph actuator it uses piezoelectric materials as the reactive materials.

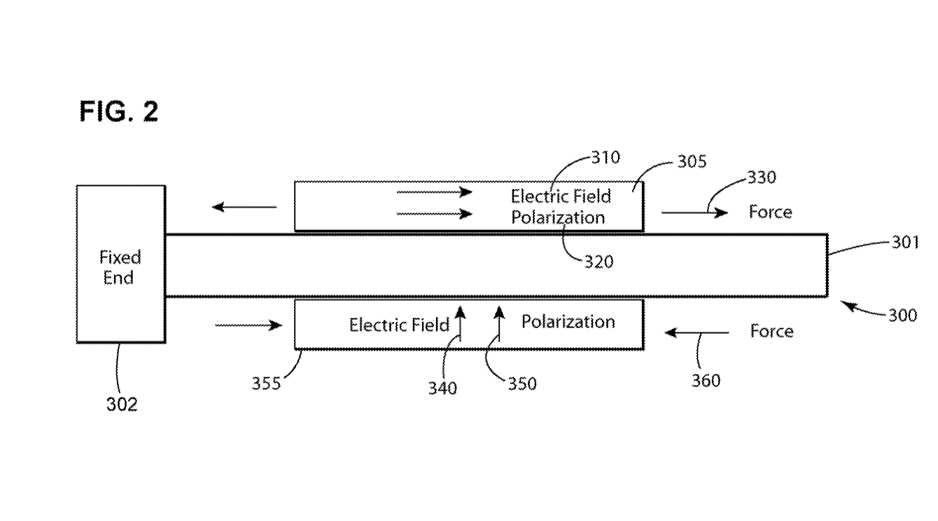

As is illustrated in FIG. 2, a bimorph actuator 300, comprised of a passive material or substrate or beam 301, fixed end 302, a top layer of active material 305 and a bottom layer of active material 355. In one embodiment the top active material 305 and the bottom active material 355 are both comprised of piezoelectric materials. The top active material 305 is polarized 320 along the plane of the material, parallel to the beam 301 of the actuator. This top active material 305 is subjected to a positive electric field 310.

In an alternate embodiment, the top active material 305 and bottom active material 355 are not separated by a passive material but are connected directly. In such an embodiment, the connection may include the presence of an adhesive, such as an epoxy, between the top active material 305 and the bottom active material 355.

The bottom active material 355 is polarized 350 through the thickness of the active material 355, perpendicular to the beam 301 of the actuator. This bottom active material is also subjected to a positive electric field 340. Although both the top active material 305 and the bottom active material 355 are subjected to a positive electric field in the direction of polarization, the actuator bends due to piezoelectric coefficients which are opposite in signs. Depending on the desired results the electric fields that are applied to the top and bottom active materials vary, and they may be the same or different strength electric fields.

In the embodiment wherein the top active material 305 and the bottom active material 355 are piezoelectric materials, the top piezoelectric material is polarized along the plane of the piezoelectric wafer such that the d33 piezoelectric coefficient is exploited (d33=374 pm/V for PZT 5A (available from Morgan Electro Ceramics, Bedford, Ohio)). The bottom piezoelectric material is polarized through the thickness such that the d31 piezoelectric coefficient is exploited (d31=−171 pm/V). Again, even though there is a positive electric field on both sides of the actuator, the actuator bends because the d33 and d31 coefficients are opposite in sign. Thus, the top expands and the bottom contracts from the piezo coefficient orientation, rather than the sign of the electric field.

As both active materials are subjected to positive electric fields, they do not exhibit the same problems as exhibited when an active material, particularly a piezoelectric material, is subjected to a negative electric field and an elevated temperature. In those cases, depolarization is seen at temperatures as low as about 50° C. In the present embodiments, there are no electric fields applied against the direction of polarization, therefore the active materials, such as piezoelectric materials, will retain their polarization at levels of at least about 50% of Curie temperature. For one common piezoelectric material PZT 5A, the piezoelectric properties are retained up to at least about 150° C., one half of Curie temperature.

The piezoelectric material can be comprised of known man made or industrial materials. For instance monolithic ceramic can be used, or a macro fiber composite (MFC) is an alternative. The MFCs have the added advantage that they result in much larger forces, and therefore greater movement is exhibited by the actuator. An MFC may be comprised of a sheet of aligned rectangular piezoceramic fibers, layered on each side with structural epoxy, which is then covered by polyimide film. The sheets of aligned rectangular piezoceramic fibers provide the added advantage of improved damage tolerance and flexibility relative to monolithic ceramics. The structural epoxy inhibits crack propagation in the ceramic and bonds the actuator components together. The polyimide film, which is the top and bottom layers of the actuator, may be comprised of an interdigitated electrode pattern on the film, and permit in-plane poling and actuation of the piezoceramic.

The fabrication process then is comprised of the creation of the piezo fibers, which are then connected or laminated to the pattern electrodes on dialectic film. The created piezoelectric components are then bonded to a substrate. MFCs can be made to size requirements, such as about 1.3 cm², so as to meet the limited spaces available for switches and relays which may, for example, be inserted in control boards of electronic devices.

An additional embodiment of the invention addresses the issue of providing power to the bimorph actuator. Due to certain desired characteristics, such as limited space, a small power source is a preferred source to operate the bimorph actuator. One embodiment of such a power source is a 3V battery. However, the power desired or required to operate the active material is 1500V when MFC is used as the active material. Therefore, a means was found in order to convert a 3V battery power source to 1500V without electrically stressing the components that go into the circuit. One means of accomplishing this was to create two halves or channels, each of which would provide half of the voltage required, connected such that the ground point was at the mid voltage point, and when combined provide 100%. In order to increase the power, a Flyback type DC to DC converter was used. In one channel, the conversion resulted in +750 volts, while in the second or alternate channel, the conversion resulted in −750 volts. The voltages are additive, and result in the desired 1500 vs for operating the actuator.

While typical embodiments have been set forth for the purpose of illustration, the foregoing descriptions should not be deemed to be a limitation on the scope herein. It is apparent that numerous other forms and modifications of this invention will occur to one skilled in the art without departing from the spirit and scope herein. The appended claims and these embodiments should be construed to cover all such obvious forms and modifications that are within the true spirit and scope of the present invention.

The following example is set forth to provide those of ordinary skill in the art with a detailed description of how the compositions and objects claimed herein are evaluated, and are not intended to limit the scope of what the inventors regard as their invention.

### EXAMPLE

A bimorph actuator comprised of PZT 5A ceramic piezoelectric material in the form of an MFC as the top and bottom active materials, toughened epoxy and Invar as the substrate was fabricated. The bimorph actuator was clamped at one end to a stationary object. An environmental chamber was used to create a uniform zone of air around the bimorph actuator at elevated temperature. The stroke of the bimorph actuator was measured with a laser measurement system through a small hole in the environmental chamber. The voltage was set to a typical operating voltage (1500 v for the top active material and 300 v for the bottom active material. The temperature was raised from 20° C. to 80° C. in ten degree increments with stroke measurements performed at each interval. The results in the following graph shows deflection within specification due to the symmetric structure.

Having described the Invention, that which is claimed is:

1. A bimorph actuator that is operational up to temperatures of about 150° C., comprising:
a top active layer;
a substrate; and
a bottom active layer.

2. The bimorph actuator of claim 1 wherein the top and bottom active layers are comprised of piezoelectric materials.

3. The bimorph actuator of claim 1 wherein the top active layer and the bottom active layer are subjected to positive electric fields.

4. The bimorph actuator of claim 3 wherein the top active layer is polarized along the plane of the material, parallel to the substrate.

5. The bimorph actuator of claim 3 wherein the bottom active layer is polarized through the thickness of the active material, perpendicular to the substrate.

6. The bimorph actuator of claim 1 that is comprised of macro fiber composites.

7. The bimorph actuator of claim 1 that further comprises a power source.

8. The power source of claim 7 that is comprised of a 3 volt battery.

9. The power source of claim 7, wherein the 3 volt batter is connected to a circuit comprising two channels, each of which provides 750 volts, for a total of 1500 volts.

10. A bimorph actuator that is operational up to temperatures of about 150° C., comprising:
a top active layer that is polarized along the plane of the material, parallel to the substrate; and
a bottom active layer that is polarized through the thickness of the layer, perpendicular to the substrate.

11. The bimorph actuator of claim 10 wherein the top active layer and the bottom active layer are comprised of piezoelectric materials.

12. The bimorph actuator of claim 10 wherein the top active layer and the bottom active layer are subject to positive electric fields.

13. The bimorph actuator of claim 10 that further comprises a power source.

14. The power source of claim 13 that is a 3 volt battery.

15. The bimorph actuator of claim 12 wherein the electric fields are not equal.

16. The bimorph actuator of claim 10 that further comprises a substrate.

17. The bimorph actuator of claim 10 that operates in small spaces.

18. A bimorph actuator that is operational up to temperatures of about 150° C., comprising:
a top active layer; and
a bottom active layer.

19. The bimorph actuator of claim 18, wherein the top active layer is connected to the bottom active layer with an adhesive.

20. A bimorph actuator that is operational up to about 50% of Curie temperature, comprising:
a top active layer; and
a bottom active layer.

21. The bimorph actuator of claim 19 that is operational in small spaces.
